(19) United States
(12) Patent Application Publication
(10) Pub. No.: US 2026/0045788 A1
(43) Pub. Date: Feb. 12, 2026

(54) AN APPARATUS FOR PROVIDING A DIRECT CURRENT (DC) OUTPUT VOLTAGE FOR A SUBSEA ELECTRICAL DEVICE

(71) Applicant: Baker Hughes Energy Technology UK Limited, Bristol (GB)

(72) Inventor: Jorge PLAZA, Bristol (GB)

(21) Appl. No.: 19/150,081

(22) PCT Filed: Jan. 22, 2024
(86) PCT No.: PCT/EP2024/025038

§ 371 Date: Jul. 22, 2025

(30) Foreign Application Priority Data
Jan. 27, 2023 (GB) 2301225.5

(51) Int. Cl. H02J 1/00; H01R 29/00; H02J 1/10; H02M 3/02; H05K 7/14

(52) U.S. Cl. CPC H02J 1/001; H01R 29/00; H02J 1/102; H02M 3/02; H05K 7/14337

(57) ABSTRACT

An apparatus for providing DC output voltage to a subsea electrical device includes an input power supply module and a plurality of DC-to-DC voltage converter modules. The input power supply module provides DC input voltage to each of the DC-to-DC voltage converter modules. Each DC-to-DC voltage converter module includes an input connector element for receiving the DC input voltage, and a plurality of output connector elements for providing a converted DC output voltage. Any of the output connector elements of one DC-to-DC voltage converter module may be electrically connected using a connecting cable element to any of the output connector elements of another DC-to-DC voltage converter module to enable one DC-to-DC voltage converter module to be electrically connected in series and/or in parallel to another DC-to-DC voltage converter module

This invention relates to an apparatus for providing a direct current (DC) output voltage for a subsea electrical device.

It is known to supply electrical energy to electrically driven devices in a subsea environment. However known electricity supply systems are complex with numerous component parts. Such complex electricity supply systems are therefore time-consuming to manufacture and configure.

This invention is aimed at providing an improved apparatus for providing a DC output voltage for a subsea electrical device which overcomes at least some of these disadvantages.

According to the invention there is provided an apparatus for providing at least one respective direct current (DC) output voltage for at least one respective subsea electrical device, comprising:
a plurality of DC-to-DC voltage converter modules each comprising at least one input connector element, for receiving a respective DC input voltage, and a plurality of output connector elements for providing a respective converted DC output voltage that is different to the respective DC input voltage;
wherein each one of the output connector elements is configured to be selectively engageable and selectively disengageable with at least one insertable connecting cable element that enables a direct electrical connection to be made between output connector elements, wherein each one of the output connector elements of a respective one of the DC-to-DC voltage converter modules is configured to be selectively, directly and re-configurably electrically connected, via the insertable connecting cable element, to at least one of the output connector elements of at least one other DC-to-DC voltage converter module of the DC-to-DC voltage converter modules, thereby enabling each one of the DC-to-DC voltage converter modules to be selectively and re-configurably electrically connected in series and/or in parallel with at least one other DC-to-DC voltage converter module of the DC-to-DC voltage converter modules; and
wherein at least one respective output connector element of the output connector elements is electrically connectable to at least one respective subsea electrical device to thereby provide at least one respective DC output voltage for the respective subsea electrical device.

The apparatus of the invention has a simple design and construction for ease of manufacturing and ease of configuration. The invention provides a low voltage modular DC to DC converter module for the energy supply of subsea electrically driven equipment.

Because the apparatus includes connections in a series configuration, this increases the output voltage, for example up to 48 VDC, for specific subsea devices. Because the apparatus includes connections in a parallel configuration, this increases the output current for high power-demanding devices. The combination of in series connections and in parallel connections provides increased current and increased voltage outputs. The in parallel connection also provides redundancy on a single channel in the case of equipment that requires a high-reliability supply. This configuration of connection channels may be performed during the manufacturing process at the hardware level.

The invention provides a low voltage DC to DC converter module (LVDCM) in the form of a single apparatus that includes independent channels for supplying energy to the subsea equipment and provides flexibility for customization. The connection of the channels in a series configuration increases the output voltage for specific subsea devices. The connection of the channels in a parallel configuration increases the output current for high-power demanding devices and provides redundancy on a single channel. The connection of channels in a combination of both in series and in parallel configurations increases both current and voltage outputs.

The plurality of DC-to-DC voltage converter modules may be contained within a housing, and each one of the output connector elements may be selectively, directly and re-configurably electrically connectable to at least one other output connector element of the output connector elements via at least one insertable connecting cable element that provides a direct electrical connection between output connector elements and that extends between output connector elements external to the housing. The housing maintains the component parts of the apparatus in a compact form and prevents damage to the component parts.

The plurality of DC-to-DC voltage converter modules may be contained with a housing, wherein each of the DC-to-DC voltage converter modules may be removable from the housing and/or may be interchangeable with another DC-to-DC voltage converter module. The housing maintains the component parts of the apparatus in a compact form and prevents damage to the component parts.

The apparatus may comprise an input power supply module that provides the respective DC input voltage to each of the DC-to-DC voltage converter modules, wherein the input connector element of each DC-to-DC voltage converter module may be connected in parallel with the input power supply module. The parallel connection results in increased current.

The input power supply module may comprise at least one electromagnetic compatibility (EMC) filter. The electromagnetic compatibility (EMC) filter filters noise on the electrical line to ensure that a quality electrical supply is fed downstream.

The respective DC input voltage may be the same and the respective DC output voltage may be the same for each of the DC-to-DC voltage converter modules.

The respective DC input voltage may be a voltage in the range of 250-500V, and may optionally be an unregulated 400V voltage. This voltage range may be particularly suitable for powering subsea equipment.

The respective DC output voltage may be a voltage in the range of 12-48V, and may optionally be a regulated 24V voltage. This voltage range may be particularly suitable for operating subsea instrumentation.

Each of the DC-to-DC voltage converter modules may have a power rating in the range of 50-150 W, and may optionally be 100 W.

Each of the DC-to-DC voltage converter modules may comprise at least one programmable communications module configured to selectively control an on/off state of the DC-to-DC voltage converter module containing the programmable communications module and/or monitor one or more operating characteristics of the DC-to-DC voltage converter module containing the programmable communications module. The programmable communications module facilitates precise user control of the operation of the DC-to-DC voltage converter module.

The operating characteristics may comprise DC input voltage and/or DC output voltage and/or DC output current and/or temperature associated with the DC-to-DC voltage converter module containing the programmable communications module.

The plurality of output connector elements of each DC-to-DC voltage converter module may comprise a plurality of positive polarity output connector elements and a plurality of negative polarity output connector elements.

The invention also provides in another aspect a subsea power network, comprising at least one subsea control module (SCM) configured to provide at least one respective DC output voltage to at least one respective subsea electrical device and comprising the apparatus of the invention for providing the at least one respective DC output voltage.

The SCM may comprise at least one subsea electronics module (SEM) and at least one power distribution and protection module (PDPM), wherein said apparatus may be contained within the PDPM. The power distribution and protection module (PDPM) distributes power and provides protection against overload and overcurrent downstream. By providing the apparatus within the PDPM, the apparatus is located close to the electrical consumers.

In another aspect of the invention there is provided a method for providing at least one respective DC output voltage for at least one respective subsea electrical device, comprising the steps of:
via at least one first direct electrical connection, each provided via at least one respective insertable connecting cable element that is engaged with, and provides a direct electrical connection between, a respective first output connector element of at least one first DC-to-DC voltage converter module and a respective second output connector element of at least one second DC-to-DC voltage converter module to thereby electrically connect the first DC-to-DC voltage converter module in series and/or in parallel with the second DC-to-DC voltage converter module, and via at least one further electrical connection between at least one third output connector element, of the first and/or second DC-to-DC voltage converter module, and at least one respective subsea electrical device, providing at least one respective DC output voltage for the respective subsea electrical device.

Because the method includes connections in series, this increases the output voltage, for example up to 48 VDC, for specific subsea electrical devices. Because the method includes connections in parallel, this increases the output current for high power-demanding subsea electrical devices. The combination of in series connections and in parallel connections provides increased current and increased voltage outputs. The in parallel connection also provides redundancy on a single channel in the case of subsea electrical equipment that requires a high-reliability supply.

Providing at least one respective DC output voltage for the respective subsea electrical device may comprise providing a plurality of respective DC output voltages for a plurality of respective subsea electrical devices.

The invention also provides in a further aspect a method for electrically connecting output connector elements associated with a plurality of DC-to-DC voltage converter modules configurable to provide at least one respective DC output voltage to at least one respective subsea electrical device, comprising the steps of:
selectively engaging each of at least one respective insertable connecting cable element with a respective first output connector element, of at least one first DC-to-DC voltage converter module, and a respective second output connector element, of at least one second DC-to-DC voltage converter module, to provide a direct electrical connection between the respective first and second output connector elements, thereby electrically connecting the first DC-to-DC voltage converter module in series and/or in parallel with the second DC-to-DC voltage converter module,
whereby at least one further output connector element of the first and/or second DC-to-DC voltage converter module is electrically connectable to at least one respective subsea electrical device to provide at least one respective DC output voltage to the respective subsea electrical device.

Because the method includes connecting in series, this increases the output voltage, for example up to 48 VDC, for specific subsea electrical devices. Because the method includes connecting in parallel, this increases the output current for high power-demanding subsea electrical devices. The combination of in series connecting and in parallel connecting provides increased current and increased voltage outputs. The in parallel connecting also provides redundancy on a single channel in the case of subsea electrical equipment that requires a high-reliability supply.

The method may comprise selectively engaging at least one said insertable connecting cable element with a negative polarity output connector element of said first DC-to-DC voltage converter module and a positive polarity output connector element of said second DC-to-DC voltage converter module to provide a direct electrical connection between the negative polarity output connector element and the positive polarity output connector element, thereby electrically connecting the first and second DC-to-DC voltage converter modules in series.

The method may comprise:
selectively engaging at least one said insertable connecting cable element with a first positive polarity output connector element of said first DC-to-DC voltage converter module and a second positive polarity output connector element of said second DC-to-DC voltage converter module to provide a direct electrical connection between the first and second positive polarity output connector elements; and
selectively engaging at least one said insertable connecting cable element with a first negative polarity output connector element of said first DC-to-DC voltage converter module and a second negative polarity output connector element of said second DC-to-DC voltage converter module to provide a direct electrical connection between the first and second negative polarity output connector elements,
thereby electrically connecting the first and second DC-to-DC voltage converter modules in parallel.

Said at least one first DC-to-DC voltage converter module may comprise DC-to-DC voltage converter module A and DC-to-DC voltage converter module B and said at least one second DC-to-DC voltage converter module may comprise DC-to-DC voltage converter module C and DC-to-DC voltage converter module D, the method may comprise:
selectively engaging at least one said insertable connecting cable element with a first negative polarity output connector element of DC-to-DC voltage converter module A and a first positive polarity output connector element of DC-to-DC voltage converter module B to provide a direct electrical connection between the first negative polarity output connector element and the first positive polarity output connector element, thereby electrically connecting DC-to-DC voltage converter modules A and B in series;
selectively engaging at least one said insertable connecting cable element with a second negative polarity output connector element of DC-to-DC voltage converter module C and a second positive polarity output connector element of DC-to-DC voltage converter module D to provide a direct electrical connection between the second negative polarity output connector element and the second positive polarity output connector element, thereby electrically connecting DC-to-DC voltage converter modules C and D in series;
selectively engaging at least one said insertable connecting cable element with a third positive polarity output connector element of DC-to-DC voltage converter module A and a fourth positive polarity output connector element of DC-to-DC voltage converter module C to provide a direct electrical connection between the third and fourth positive polarity output connector elements; and
selectively engaging at least one said insertable connecting cable element with a third negative polarity output connector element of DC-to-DC voltage converter module B and a fourth negative polarity output connector element of DC-to-DC voltage converter module D to provide a direct electrical connection between the third and fourth negative polarity output connector elements,
thereby electrically connecting the series connection of DC-to-DC voltage converter modules A and B and the series connection of DC-to-DC voltage converter modules C and D in parallel.

An embodiment of the invention will be described hereinafter, by way of example only, with reference to the accompanying drawings, in which:

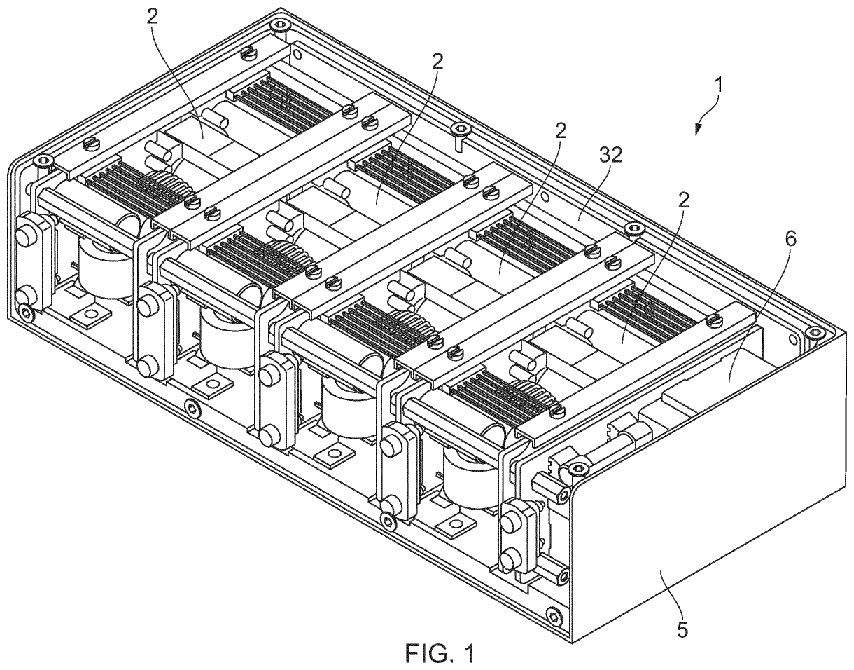

FIG. 1 is a partially cut-away, perspective view of an apparatus according to the invention,

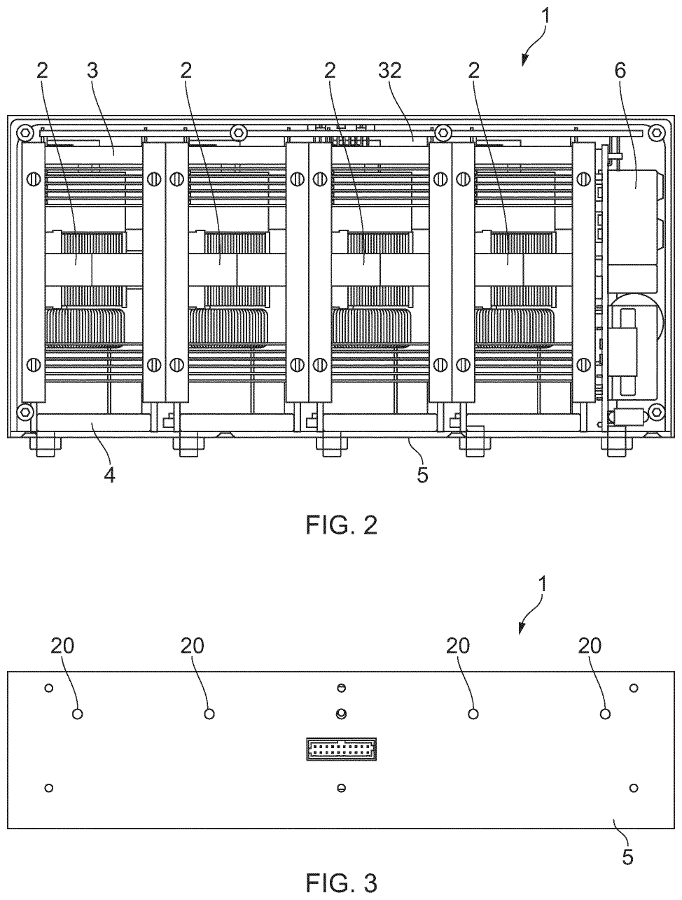

FIG. 2 is a plan view of the apparatus of FIG. 1,

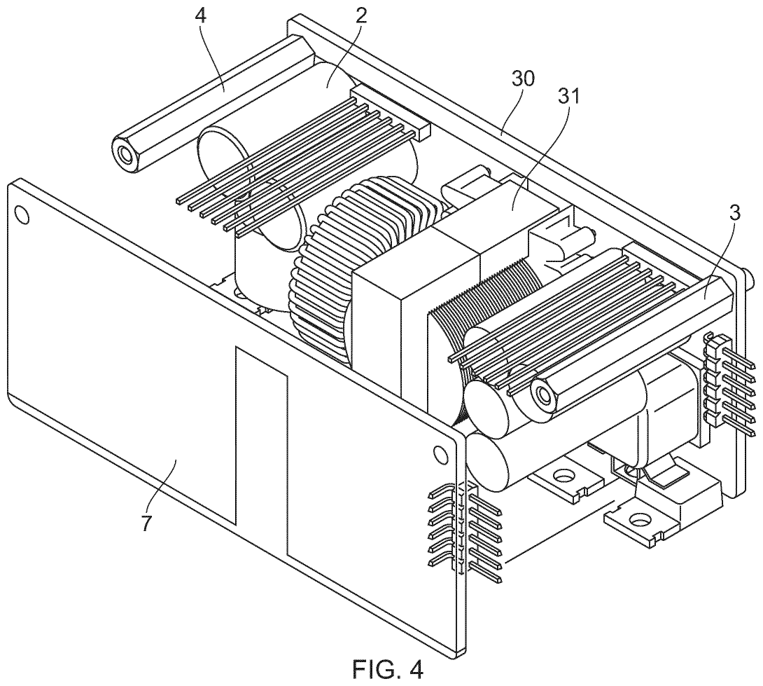

FIG. 3 is a rear view of the apparatus of FIG. 1,

FIG. 4 is a perspective view of a DC-to-DC voltage converter module of the apparatus of FIG. 1,

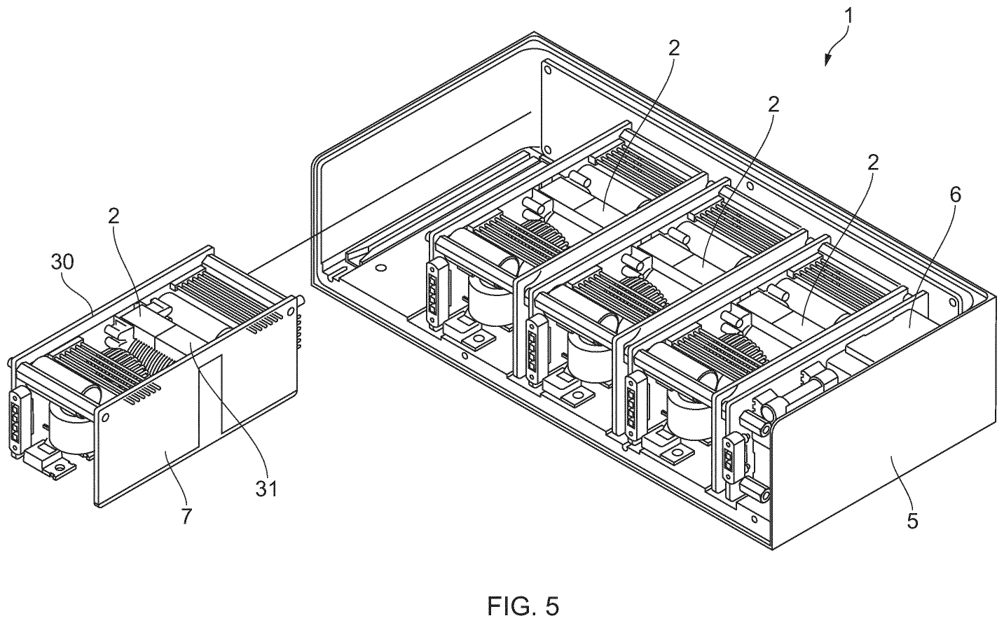

FIGS. 5 to 10 are perspective views illustrating assembly of the apparatus of FIG. 1,

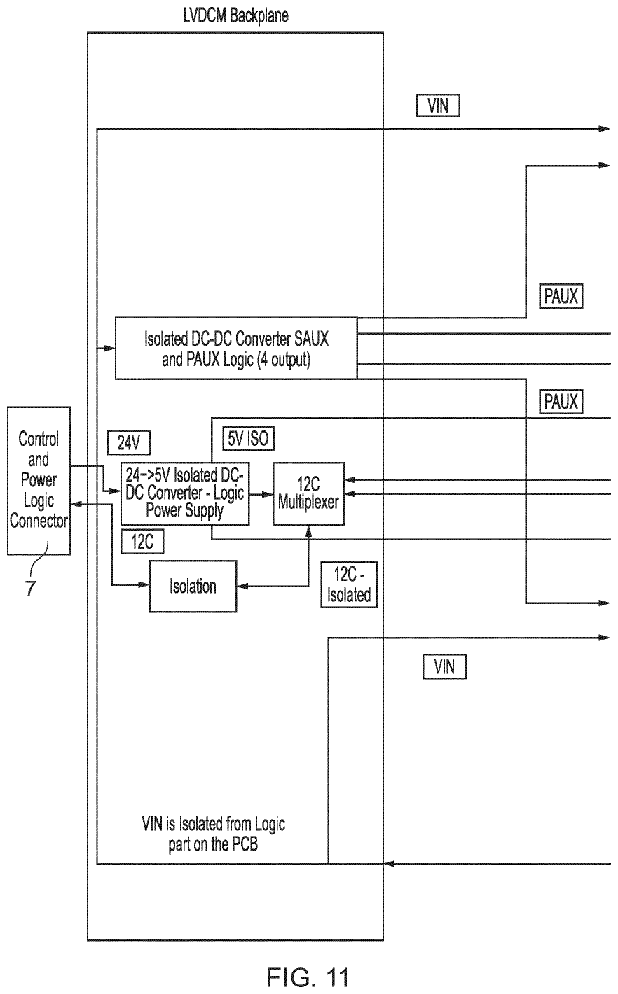

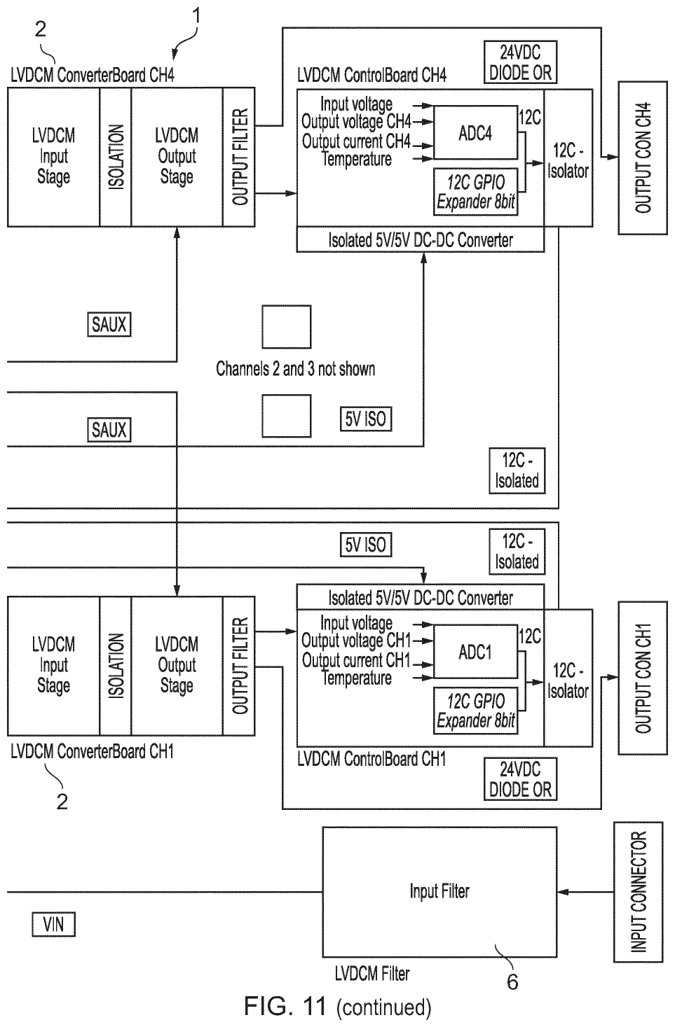

FIG. 11 is a schematic illustration of the apparatus of FIG. 1, and

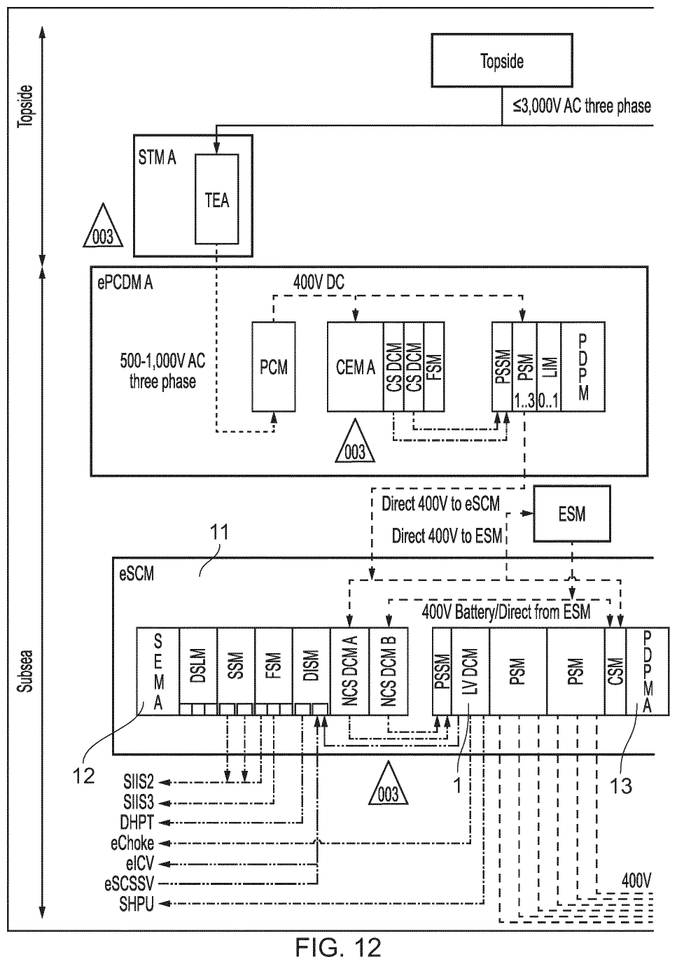

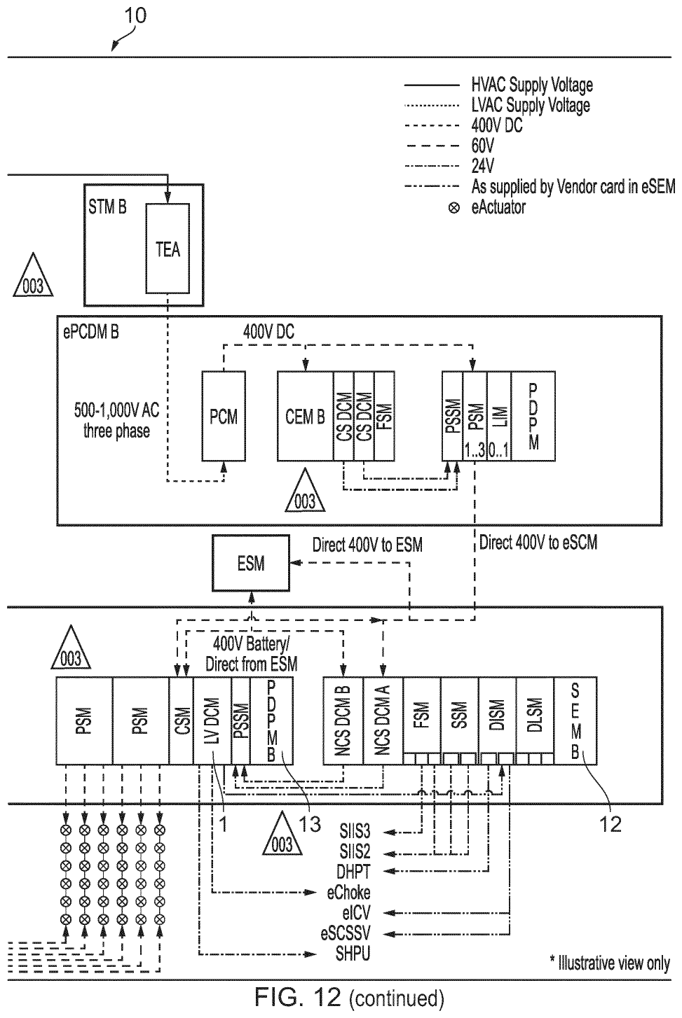

FIG. 12 is a schematic illustration of a subsea power network according to the invention.

In the drawings like reference numerals refer to like parts.

Referring to the drawings, and initially to FIG. 1 thereof, there is illustrated an apparatus 1 according to the invention. The apparatus 1 may be employed to provide one or more DC output voltages to one or more respective subsea electrical devices.

The apparatus 1 includes an input power supply module 6. In this case the input power supply module 6 is provided in the form of an electromagnetic compatibility (EMC) filter.

The apparatus 1 includes a plurality of DC-to-DC voltage converter modules 2. In this case the apparatus 1 includes four DC-to-DC voltage converter modules 2. The input power supply module 6 provides the respective DC input voltage to each of the DC-to-DC voltage converter modules 2. The respective DC input voltage is the same for each of the DC-to-DC voltage converter modules 2. In this case the DC input voltage is a voltage in the range of from 250V to 500V. For example the DC input voltage may be an unregulated 400V voltage.

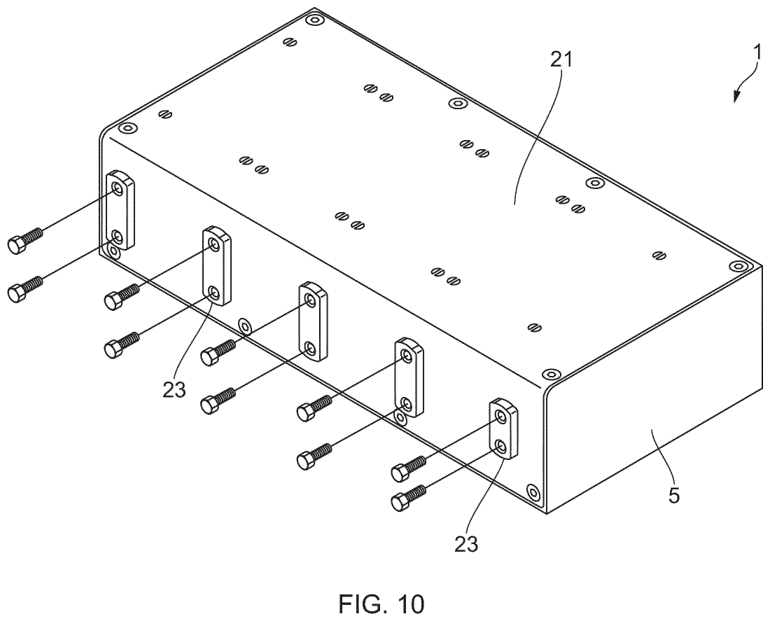

The DC-to-DC voltage converter modules 2 are contained within a housing 5 (FIG. 10). As illustrated in FIG. 5, each of the DC-to-DC voltage converter modules 2 is removable from the housing 5. Each DC-to-DC voltage converter module 2 may be interchanged with another DC-to-DC voltage converter module 2. The housing 5 may be of any suitable material, such as aluminium.

Each DC-to-DC voltage converter module 2 includes at least one input connector element 3 for receiving the DC input voltage, and a plurality of output connector elements 4 for providing a converted DC output voltage (FIG. 4). The input connector element 3 of each DC-to-DC voltage converter module 2 is connected in parallel with the input power supply module 6. The output connector elements 4 of each DC-to-DC voltage converter module 2 include a plurality of positive polarity output connector elements and a plurality of negative polarity output connector elements. Each DC-to-DC voltage converter module 2 includes a converterboard 30, and an isolation element 31.

For each DC-to-DC voltage converter module 2, the converted DC output voltage is different to the DC input voltage.

The respective DC output voltage is the same for each of the DC-to-DC voltage converter modules 2. In this case the DC output voltage is a voltage in the range of from 12V to 48V. For example the DC output voltage may be a regulated 24V voltage.

In this case each of the DC-to-DC voltage converter modules 2 has a power rating in the range of from 50 W to 150 W. For example the power rating may be 100 W.

Each DC-to-DC voltage converter module 2 includes a programmable communications module 7 (FIG. 4). The programmable communications module 7 facilitates selective user control of an on/off state of the DC-to-DC voltage converter module 2. The programmable communications module 7 also facilitates user monitoring of operating characteristics of the DC-to-DC voltage converter module 2, such as the DC input voltage, and/or the DC output voltage, and/or the DC output current, and/or the temperature associated with the DC-to-DC voltage converter module 2.

Each DC-to-DC voltage converter module 2 includes means to indicate an operating state, for example a plurality of user visible Light Emitting Diodes (LEDs) 20, as illustrated in FIG. 3. The LEDs 20 may be employed for diagnostic purposes. For example the apparatus 1 may include internally powered health monitoring circuity to provide the following external indicators. The LEDs 20 may indicate the operational status of the apparatus 1 by the following illumination:

### Input:

GREEN: apparatus OK=Input ON and in range.
Red: apparatus Fault or Input out of range.
OFF: apparatus Input OFF
   ·Channel status:
GREEN: apparatus Channel output ON and in range
RED: apparatus Channel output OFF or out of range
OFF: DC power input OFF or out of range.

The telemetry and external diagnostic information may remain available independent of the status of the apparatus input power. For example the 400V DC input voltage may be used for supplying downstream instruments. The 24V DC output voltage may be used for powering the programmable communications module 7. In the event that the 400V DC input voltage supply is lost, the telemetry data will still be obtainable. In the event that the 24V DC output voltage is lost, the apparatus 1 may be configured to enter a safe state (Open circuit). In the safe state telemetry data transfer ceases.

It may be possible to obtain housekeeping telemetry from the apparatus 1 with the unit powered on and off. The remaining unused expanders I/O ports may be used for additional diagnostics features or other functions, with seven bits for each module.

Each of the output connector elements 4 may be selectively engaged with an insertable connecting cable element. The connecting cable element enables a direct electrical connection to be made between output connector elements 4 of different DC-to-DC voltage converter modules 2. The connecting cable element extends between the output connector elements 4 external to the housing 5. The connecting cable element may also be selectively disengaged from the output connector element 4.

In this manner any of the output connector elements 4 of one DC-to-DC voltage converter module 2 may be selectively, directly and re-configurably electrically connected, via the connecting cable element, to any of the output connector elements 4 of another DC-to-DC voltage converter module 2. The apparatus 1 thus enables one DC-to-DC voltage converter module 2 to be selectively and re-configurably electrically connected in series and/or in parallel with another DC-to-DC voltage converter module 2.

One of the output connector elements 4 of the DC-to-DC voltage converter module 2 may also be electrically connected to a subsea electrical device. In this manner the DC output voltage may be provided to the subsea electrical device.

The apparatus 1 may be integrated as part of a subsea power and communications network 10 (FIG. 12). In this case the subsea power and communications network 10 includes a subsea control module (SCM) 11. The subsea control module 11 includes a subsea electronics module (SEM) 12 and a power distribution and protection module (PDPM) 13. The apparatus 1 is incorporated as part of the power distribution and protection module 13 of the subsea control module 11. The apparatus 1 as part of the subsea control module 11 provides the DC output voltage to the subsea electrical device.

In use, the input power supply module 6 is connected in parallel to the input connector element 3 of each DC-to-DC voltage converter module 2. The input power supply module 6 provides the respective DC input voltage to the input connector element 3 of each DC-to-DC voltage converter modules 2.

One end of a connecting cable element is engaged with an output connector element 4 of one DC-to-DC voltage converter module 2. The other end of the connecting cable element is engaged with an output connector element 4 of another DC-to-DC voltage converter module 2 to achieve a direct electrical connection between the output connector elements 4 of the two DC-to-DC voltage converter modules 2. The connecting cable element extends between the output connector elements 4 external to the housing 5.

It will be appreciated that the two DC-to-DC voltage converter modules 2 may be electrically connected in series and/or in parallel.

For example a connecting cable element may be engaged with a negative polarity output connector element 4 of a first DC-to-DC voltage converter module 2, and the connecting cable element may be engaged with a positive polarity output connector element 4 of a second DC-to-DC voltage converter module 2. In this manner a direct electrical connection is established between the negative polarity output connector element 4 and the positive polarity output connector element 4. The first DC-to-DC voltage converter module 2 and the second DC-to-DC voltage converter module 2 are thus electrically connected in series.

As another example one connecting cable element may be engaged with a first positive polarity output connector element 4 of a first DC-to-DC voltage converter module 2, and the connecting cable element may be engaged with a second positive polarity output connector element 4 of a second DC-to-DC voltage converter module 2. In this manner a direct electrical connection is established between the first positive polarity output connector element 4 and the second positive polarity output connector element 4. Another connecting cable element may be engaged with a first negative polarity output connector element 4 of the first DC-to-DC voltage converter module 2, and the connecting cable element may be engaged with a second negative polarity output connector element 4 of the second DC-to-DC voltage converter module 2. In this manner a direct electrical connection is established between the first negative polarity output connector element 4 and the second negative polarity output connector element 4. The first DC-to-DC voltage converter module 2 and the second DC-to-DC voltage converter module 2 are thus electrically connected in parallel.

As another example one connecting cable element may be engaged with a first negative polarity output connector element 4 of a DC-to-DC voltage converter module 2A, and the connecting cable element may be engaged with a first positive polarity output connector element 4 of a DC-to-DC voltage converter module 2B. In this manner a direct electrical connection is established between the first negative polarity output connector element 4 and the first positive polarity output connector element 4. The DC-to-DC voltage converter module 2A and the DC-to-DC voltage converter module 2B are thus electrically connected in series. Another connecting cable element may be engaged with a second negative polarity output connector element 4 of a DC-to-DC voltage converter module 2C, and the connecting cable element may be engaged with a second positive polarity output connector element 4 of a DC-to-DC voltage converter module 2D. In this manner a direct electrical connection is established between the second negative polarity output connector element 4 and the second positive polarity output connector element 4. The DC-to-DC voltage converter module 2C and the DC-to-DC voltage converter module 2D are thus electrically connected in series. Another connecting cable element may be engaged with a third positive polarity output connector element 4 of the DC-to-DC voltage converter module 2A, and the connecting cable element may be engaged with a fourth positive polarity output connector element 4 of the DC-to-DC voltage converter module 2C. In this manner a direct electrical connection is established between the third positive polarity output connector element 4 and the fourth positive polarity output connector element 4. Another connecting cable element may be engaged with a third negative polarity output connector element 4 of the DC-to-DC voltage converter module 2B, and the connecting cable element may be engaged with a fourth negative polarity output connector element 4 of the DC-to-DC voltage converter module 2D. In this manner a direct electrical connection is established between the third negative polarity output connector element 4 and the fourth negative polarity output connector element 4. The series connection of the DC-to-DC voltage converter modules 2A, 2B and the series connection of the DC-to-DC voltage converter modules 2C, 2D are thus electrically connected in parallel.

One of the output connector elements 4 of one of the DC-to-DC voltage converter modules 2 is electrically connected to the subsea electrical device. The apparatus 1 may thus be employed to provide the DC output voltage to the subsea electrical device.

It will be appreciated that an output connector element 4 of several of the DC-to-DC voltage converter modules 2 may be electrically connected to several subsea electrical devices. The apparatus 1 may thus be employed to simultaneously provide DC output voltages to more than one subsea electrical device.

The user controls the on/off state of the DC-to-DC voltage converter module 2, and monitors the operating characteristics of the DC-to-DC voltage converter module 2 using the programmable communications module 7.

The apparatus 1 has a modular configuration. The apparatus 1 may operate with any suitable number of DC-to-DC voltage converter modules 2. As illustrated in FIG. 5, the DC-to-DC voltage converter modules 2 are selectively interchangeable.

In this case the four low voltage DC-to-DC voltage converter modules 2 provide four independent channels to convert 400VDC into 24VDC for supplying energy to the subsea equipment. The configuration of the channels connected in series increases the output voltage up to 48VDC for specific subsea devices. The connection of the channels in parallel increases the output current for high power-demanding devices. The combination of in series and in parallel connections provides increased current and increased voltage outputs. The in parallel connection also provides redundancy on a single channel for equipment that requires a high-reliability supply.

In further detail the apparatus 1 may include the input filter 6, the four identical power sub-modules 2 (ConverterBoard) with four identical corresponding control modules 7 (ControlBoard), power distribution and backplane module (Backplane), as illustrated in FIG. 11. Each power sub-module 2 may include a 100 W DC-DC Converter having a high power part, a transformer, power transistors, power diodes, a transistor driver, a control IC, and an output filter. Each control module 2 may include an analogue to digital converter, a i2c GPIO expander, telemetry and diagnostic circuits. The input filter board 6 may include an EMC input filter and mains input protections. The backplane module may include power and communication circuitry for power and communication distribution between boards as well as to facilitate connection with control equipment.

A backplane 32 of the apparatus 1 includes an I2C Multiplexer, a 24-5 VDC converter, and power and communications distribution (FIG. 1).

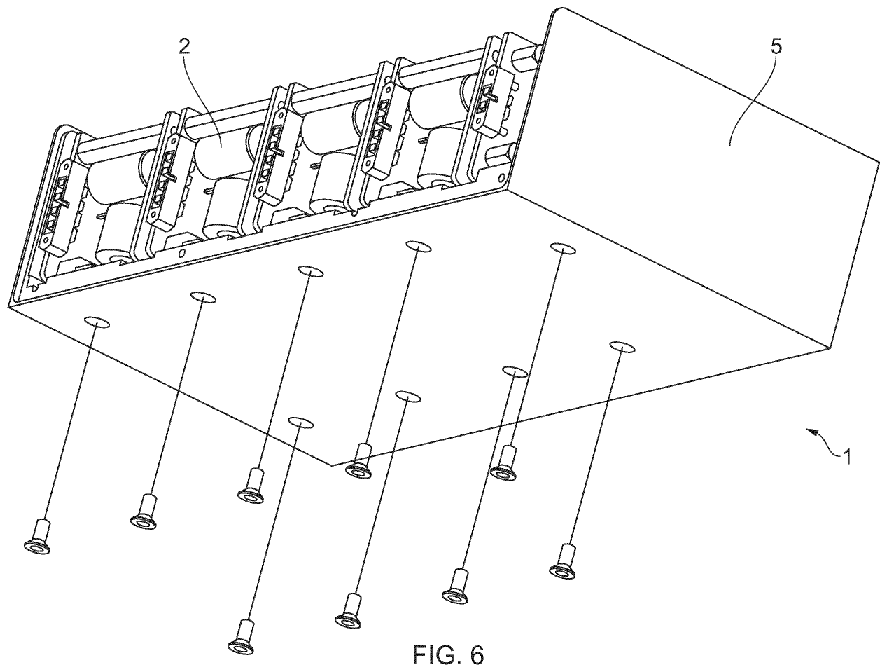

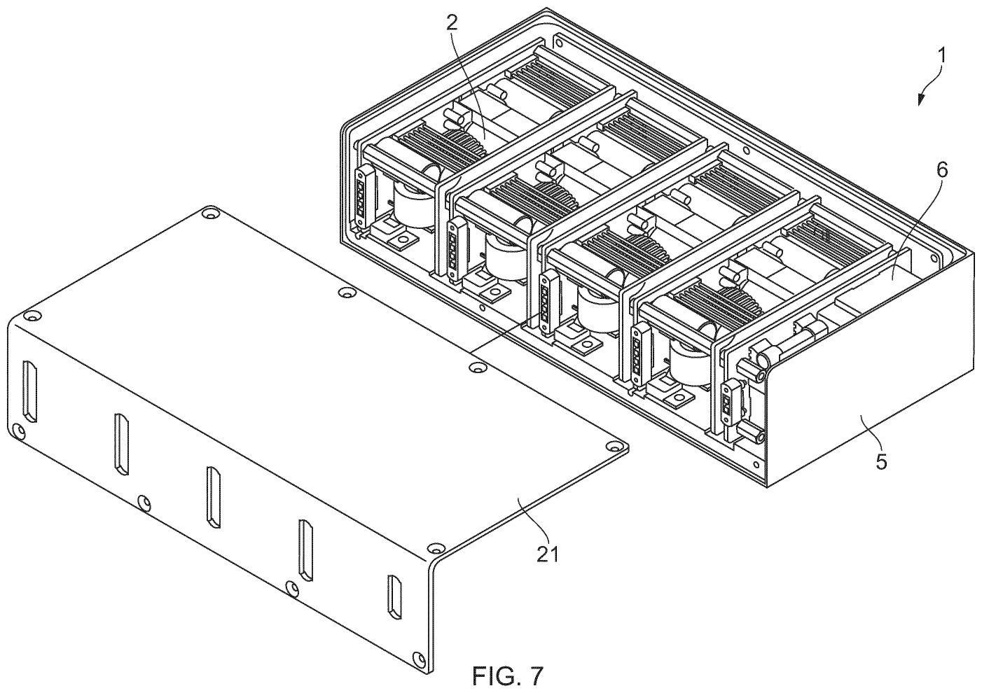

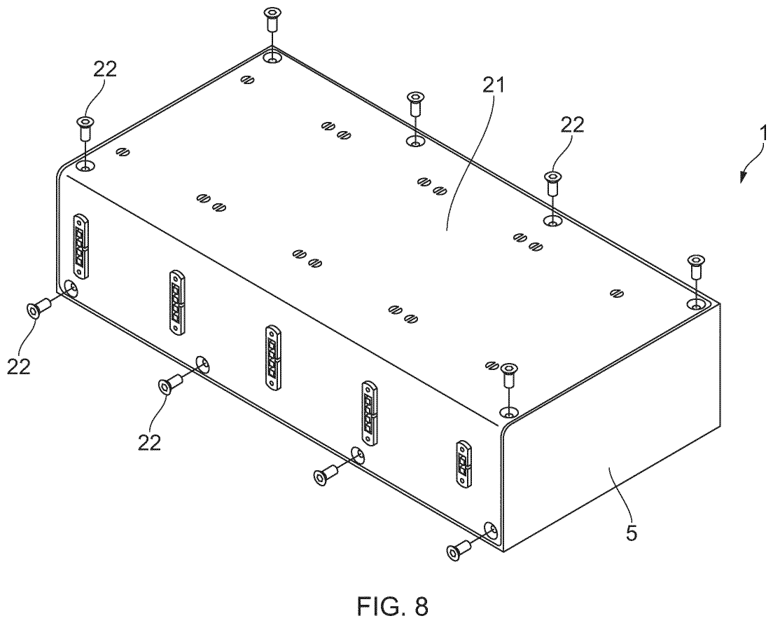

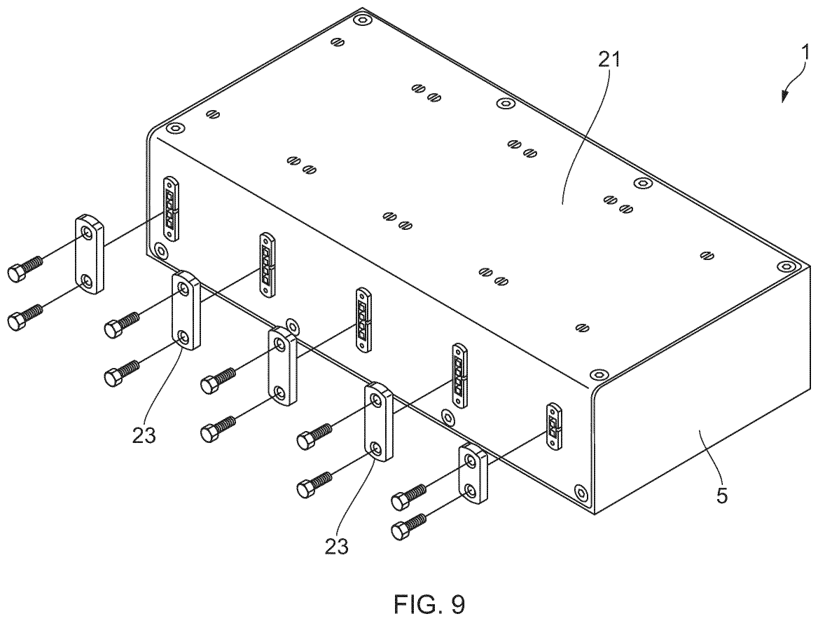

FIG. 4 illustrates the power PCB and signal PCB. FIG. 5 illustrates one of the four modules 2 slide out of the chassis 5. FIG. 6 illustrates the PCB screw thread lock assembly. FIG. 7 illustrates assembling the upper chassis cover 21. FIG. 8 illustrates the chassis top cover screws 22. FIG. 9 illustrates the power socket safety cover 23 removed. FIG. 10 illustrates the power socket safety cover 23 fitted.

The mains power supply connection may be located on the filter PCB. The power supply may be connected into the distribution PCB at the back panel. The back panel distributes power and signals into each of the power channels and power control boards. Each channel may have two PCBs, a first for high power circuit and a second for logic and control. All internal connections between boards may be made by 2.54 mm pin headers.

FIG. 12 illustrates a pathway of the DC voltage from the topside to the subsea electrical device. The transformer module TEA, which is applicable to AC systems only, converts incoming supply to 600VAC. The power converter module PCM converts the topside supply (up to 1500VDC/3000VAC) into regulated 400VDC. FIG. 12 illustrates the power and communications distribution module ePCDM. The communications electronic module eCEM acts as a router for distributing communications. The DC-DC converter module DCM generates 60VDC from 400VDC for the internal operation of the CEM/SEM. The fieldbus support module FSM provides a communications interface (CAN/RS485/RS422) to communicate with other parts of the system. The power distribution and protection module ePDPM acts as a switch for power distribution. The power switch module PSM is a transistor switch for switching power to actuators. The line insulation monitor LIM checks insulation resistance to detect faults. The power supervisory system module PSSM acts as a communication interface between PSM/LIM and the rest of the system. FIG. 12 illustrates the subsea control module eSCM. The subsea electronic module eSEM acts as an interface between the system and downstream actuators and instrumentation. The energy storage module ESM provides 400VDC to the system in case of topside power failure.

Throughout the description and claims of this patent specification, the words “comprise” and “contain” and variations of them mean “including but not limited to” and they are not intended to and do not exclude other moieties, additives, components, integers or steps. Throughout the description and claims of this patent specification, the singular encompasses the plural unless the context otherwise requires. In particular, where the indefinite article is used, the patent specification is to be understood as contemplating plurality as well as singularity, unless the context requires otherwise.

Features, integers, characteristics or groups described in conjunction with a particular aspect, embodiment or example of the invention are to be understood to be applicable to any other aspect, embodiment or example described herein unless incompatible therewith. All of the features disclosed in this patent specification including any accompanying claims, abstract and drawings, and/or all of the steps of any method or process so disclosed, may be combined in any combination, except combinations where at least some of the features and/or steps are mutually exclusive. The invention is not restricted to any details of any foregoing embodiments. The invention extends to any novel one, or novel combination, of the features disclosed in this patent specification including any accompanying claims, abstract and drawings, or to any novel one, or any novel combination, of the steps of any method or process so disclosed.

The reader's attention is directed to all papers and documents which are filed concurrently with or previous to this patent specification in connection with this patent application and which are open to public inspection with this patent specification, and the contents of all such papers and documents are incorporated herein by reference.

1-20. (canceled)

21. An apparatus for providing at least one respective DC output voltage for at least one respective subsea electrical device, comprising:
a plurality of DC-to-DC voltage converter modules each comprising at least one input connector element, for receiving a respective DC input voltage, and a plurality of output connector elements for providing a respective converted DC output voltage that is different to the respective DC input voltage;
wherein each one of the output connector elements is configured to be selectively engageable and selectively disengageable with at least one insertable connecting cable element that enables a direct electrical connection to be made between output connector elements;
wherein each one of the output connector elements of a respective one of the DC-to-DC voltage converter modules is configured to be selectively, directly and re-configurably electrically connected, via the insertable connecting cable element, to at least one of the output connector elements of at least one other DC-to-DC voltage converter module of the DC-to-DC voltage converter modules, thereby enabling each one of the DC-to-DC voltage converter modules to be selectively and re-configurably electrically connected in series and/or in parallel with at least one other DC-to-DC voltage converter module of the DC-to-DC voltage converter modules; and,
wherein at least one respective output connector element of the output connector elements is electrically connectable to at least one respective subsea electrical device to thereby provide at least one respective DC output voltage for the respective subsea electrical device.

22. The apparatus as claimed in claim 21, further comprising:
the plurality of DC-to-DC voltage converter modules are contained within a housing, and wherein each one of the output connector elements is selectively, directly and re-configurably electrically connectable to at least one other output connector element of the output connector elements via at least one insertable connecting cable element that provides a direct electrical connection between output connector elements and that extends between output connector elements external to the housing.

23. The apparatus as claimed in claim 21, further comprising: the plurality of DC-to-DC voltage converter modules are contained with a housing, wherein each of the DC-to-DC voltage converter modules is removable from the housing and/or is interchangeable with another DC-to-DC voltage converter module.

24. The apparatus as claimed in claim 21, further comprising:
an input power supply module that provides the respective DC input voltage to each of the DC-to-DC voltage converter modules, wherein the input connector element of each DC-to-DC voltage converter module is connected in parallel with the input power supply module.

25. The apparatus as claimed in claim 24, further comprising:
the input power supply module comprises at least one electromagnetic compatibility (EMC) filter.

26. The apparatus as claimed in claim 21, further comprising:
the respective DC input voltage is the same and the respective DC output voltage is the same for each of the DC-to-DC voltage converter modules.

27. The apparatus as claimed in claim 21, further comprising:
the respective DC input voltage is a voltage in the range of 250-500V, and is optionally an unregulated 400V voltage.

28. The apparatus as claimed in claim 21, further comprising:
the respective DC output voltage is a voltage in the range of 12-48V, and is optionally a regulated 24V voltage.

29. The apparatus as claimed in claim 21, further comprising:
each of the DC-to-DC voltage converter modules have a power rating in the range of 50-150 W, and is optionally 100 W.

30. The apparatus as claimed in claim 21, wherein each of the DC-to-DC voltage converter modules further comprises:
at least one programmable communications module configured to selectively control an on/off state of the DC-to-DC voltage converter module containing the programmable communications module and/or monitor one or more operating characteristics of the DC-to-DC voltage converter module containing the programmable communications module.

31. The apparatus as claimed in claim 30, further comprising:
the operating characteristics comprise DC input voltage and/or DC output voltage and/or DC output current and/or temperature associated with the DC-to-DC voltage converter module containing the programmable communications module.

32. The apparatus as claimed in claim 21, further comprising:
the plurality of output connector elements of each DC-to-DC voltage converter module comprises a plurality of positive polarity output connector elements and a plurality of negative polarity output connector elements.

33. A subsea power network, comprising:
at least one subsea control module (SCM) configured to provide at least one respective DC output voltage to at least one respective subsea electrical device and comprising the apparatus as claimed in claim 21 for providing the at least one respective DC output voltage.

34. The subsea power network as claimed in claim 33, further comprising:
the SCM comprises at least one subsea electronics module (SEM) and at least one power distribution and protection module (PDPM), wherein said apparatus is contained within the PDPM.

35. A method for providing at least one respective DC output voltage for at least one respective subsea electrical device, comprising the steps of:
via at least one first direct electrical connection, each provided via at least one respective insertable connecting cable element that is engaged with, and provides a direct electrical connection between, a respective first output connector element of at least one first DC-to-DC voltage converter module and a respective second output connector element of at least one second DC-to-DC voltage converter module to thereby electrically connect the first DC-to-DC voltage converter module in series and/or in parallel with the second DC-to-DC voltage converter module, and via at least one further electrical connection between at least one third output connector element, of the first and/or second DC-to-DC voltage converter module, and at least one respective subsea electrical device, providing at least one respective DC output voltage for the respective subsea electrical device.

36. The method as claimed in claim 35, further comprising:
providing at least one respective DC output voltage for the respective subsea electrical device comprises providing a plurality of respective DC output voltages for a plurality of respective subsea electrical devices.

37. A method for electrically connecting output connector elements associated with a plurality of DC-to-DC voltage converter modules configurable to provide at least one respective DC output voltage to at least one respective subsea electrical device, comprising the steps of:
selectively engaging each of at least one respective insertable connecting cable element with a respective first output connector element, of at least one first DC-to-DC voltage converter module, and a respective second output connector element, of at least one second DC-to-DC voltage converter module, to provide a direct electrical connection between the respective first and second output connector elements, thereby electrically connecting the first DC-to-DC voltage converter module in series and/or in parallel with the second DC-to-DC voltage converter module,
whereby at least one further output connector element of the first and/or second DC-to-DC voltage converter module is electrically connectable to at least one respective subsea electrical device to provide at least one respective DC output voltage to the respective subsea electrical device.

38. The method as claimed in claim 37, further comprising:
selectively engaging at least one said insertable connecting cable element with a negative polarity output connector element of said first DC-to-DC voltage converter module and a positive polarity output connector element of said second DC-to-DC voltage converter module to provide a direct electrical connection between the negative polarity output connector element and the positive polarity output connector element, thereby electrically connecting the first and second DC-to-DC voltage converter modules in series.

39. The method as claimed in claim 37, further comprising:
selectively engaging at least one said insertable connecting cable element with a first positive polarity output connector element of said first DC-to-DC voltage converter module and a second positive polarity output connector element of said second DC-to-DC voltage converter module to provide a direct electrical connection between the first and second positive polarity output connector elements; and,
selectively engaging at least one said insertable connecting cable element with a first negative polarity output connector element of said first DC-to-DC voltage converter module and a second negative polarity output connector element of said second DC-to-DC voltage converter module to provide a direct electrical connection between the first and second negative polarity output connector elements,
thereby electrically connecting the first and second DC-to-DC voltage converter modules in parallel.

40. The method as claimed in claim 37, wherein said at least one first DC-to-DC voltage converter module comprises DC-to-DC voltage converter module A and DC-to-DC voltage converter module B and wherein said at least one second DC-to-DC voltage converter module comprises DC-to-DC voltage converter module C and DC-to-DC voltage converter module D, the method further comprising:
selectively engaging at least one said insertable connecting cable element with a first negative polarity output connector element of DC-to-DC voltage converter module A and a first positive polarity output connector element of DC-to-DC voltage converter module B to provide a direct electrical connection between the first negative polarity output connector element and the first positive polarity output connector element, thereby electrically connecting DC-to-DC voltage converter modules A and B in series;
selectively engaging at least one said insertable connecting cable element with a second negative polarity output connector element of DC-to-DC voltage converter module C and a second positive polarity output connector element of DC-to-DC voltage converter module D to provide a direct electrical connection between the second negative polarity output connector element and the second positive polarity output connector element, thereby electrically connecting DC-to-DC voltage converter modules C and D in series;
selectively engaging at least one said insertable connecting cable element with a third positive polarity output connector element of DC-to-DC voltage converter module A and a fourth positive polarity output connector element of DC-to-DC voltage converter module C to provide a direct electrical connection between the third and fourth positive polarity output connector elements; and,
selectively engaging at least one said insertable connecting cable element with a third negative polarity output connector element of DC-to-DC voltage converter module B and a fourth negative polarity output connector element of DC-to-DC voltage converter module D to provide a direct electrical connection between the third and fourth negative polarity output connector elements, thereby electrically connecting the series connection of DC-to-DC voltage converter modules A and B and the series connection of DC-to-DC voltage converter modules C and D in parallel.
